(19) United States
(12) Patent Application Publication
(10) Pub. No.: US 2023/0368974 A1
(43) Pub. Date: Nov. 16, 2023

(54) EDGE-MILLED MAGNETIC WIRE AND MANUFACTURE THEREOF

(71) Applicants: Samsung Electronics Co., Ltd., Suwon-si (KR); SNU R&DB FOUNDATION, Seoul (KR)

(72) Inventors: Sug-Bong CHOE, Seoul (KR); Myeonghoe KIM, Seoul (KR); Yune-Seok NAM, Seoul (KR); Joon Moon, Seoul (KR); Seong-Hyub LEE, Seoul (KR)

(73) Assignees: Samsung Electronics Co., Ltd., Suwon-si (KR); SNU R&DB FOUNDATION, Seoul (KR)

(21) Appl. No.: 18/117,785

(22) Filed: Mar. 6, 2023

(30) Foreign Application Priority Data
May 13, 2022 (KR) 10-2022-0059166

(51) Int. Cl. H01F 41/14; H01F 1/00; H01F 1/12; H01F 5/00

(52) U.S. Cl. CPC H01F 41/14; H01F 1/0018; H01F 1/12; H01F 5/00

(57) ABSTRACT

A method of manufacturing a magnetic wire example includes depositing a magnetic film, which has a composition that enables measuring motion of a magnetic domain wall in the magnetic film, on/above a silicon substrate, forming the magnetic film on the silicon substrate on which the magnetic film is deposited using a wire pattern and an electrode pattern of a certain specification, shielding a central part of the magnetic wire in a photolithography method by an edge milling pattern which corresponds to a predetermined specification, and ablating an edge portion of the magnetic wire which is not shielded by an ion milling.

### CROSS-REFERENCE TO RELATED APPLICATIONS

This application claims the benefit under 35 USC § 119(a) of Korean Patent Application No. 10-2022-0059166, filed on May 13, 2022, in the Korean Intellectual Property Office, the entire disclosure of which is incorporated herein by reference for all purposes.

### BACKGROUND

### 1. Field

The following description relates to edge-milled magnetic wires and manufacturing method thereof.

### 2. Description of Related Art

Various devices which store and process information using a magnetic body are being developed, such devices include magnetic random access memory (MRAM) or racetrack memory.

Racetrack memory reads the magnetization state and processes it as information using a magnetic tunnel junction when a magnetic domain wall is moved by a spin current, which is caused by application of electricity to a magnetic-body thin film which has a magnetization axis that can easily vary between vertical and horizontal.

### SUMMARY

This summary is provided to introduce a selection of concepts in a simplified form that are further described below in the detailed description. This summary is not intended to identify key features or essential features of the claimed subject matter, nor is it intended to be used as an aid in determining the scope of the claimed subject matter.

In one general aspect, a method of manufacturing a magnetic wire may include depositing a magnetic film, which has a composition for measuring a motion of a magnetic domain wall in the magnetic film, above a silicon substrate, forming a magnetic wire on the silicon substrate, above which the magnetic film is deposited, using a wire pattern and an electrode pattern of a predetermined specification, shielding a central part of the magnetic wire in a photolithography method by an edge milling pattern corresponding to the predetermined specification, and ablating the edge portion of the unshielded magnetic wire by ion-milling.

The ablating of the edge portion may include reducing the edge portion of the magnetic wire to a thickness at which a current flows in the edge portion but a magnetic layer is not magnetized.

The ablating of the edge portion of the magnetic wire may include measuring a polar-magneto-optical Kerr effect (P-MOKE) of the edge portion of the magnetic wire and ablating the edge portion of the magnetic wire to a thickness at which a current flows in the edge portion but a magnetic layer is not magnetized, using a result of the measuring of the P-MOKE.

The ablating of the edge portion of the magnetic wire may include cutting a magnetic layer of the edge portion to a thickness ratio of 0.0075% of an total width of the magnetic wire.

The ablating of the edge portion of the magnetic wire may reduce a width of an ablated layer of the magnetic wire to one half of the total width of the magnetic wire.

The ablating of the edge portion of the magnetic wire may include etching the edge portion of the magnetic wire down through a magnetic layer, using argon (Ar) ion-beam etching.

The magnetic film may include a magnetic film of perpendicular magnetic anisotropy having a vertical magnetization state.

The depositing of the magnetic film on/above the silicon substrate may include depositing the magnetic film on/above the silicon substrate using direct current (DC) magnetron sputtering.

The wire pattern may have a pattern wire width that is wider width than a width W of the magnetic wire, and the magnetic film may be deposited, using a photolithography.

In another general aspect, a magnetic wire includes opposing edge portions, where each edge portion is cut in a predetermined width ratio relative to a total width of the magnetic wire so that a magnetic domain wall of the magnetic wire does not tilt due to an Oersted field which occurs due to a current applied to the magnetic wire.

The predetermined width ratio may include a width ratio of ¼ of the total width of the magnetic wire.

The edge portion may be cut to a thickness at which the current flows in the edge portion but a magnetic layer of the edge portion is not magnetized.

The magnetic layer of the edge portion may be cut to 0.0075% of the total width of the magnetic wire.

The magnetic wire may be down through a magnetic layer of the edge portion through Ar ion-beam etching.

The edge portion may be cut to a thickness at which the current flows in the edge portion but a magnetic layer of the edge portion is not magnetized, and a central part of the magnetic wire is shielded in a photolithography method by an edge milling pattern corresponding to a predetermined specification.

In one general aspect, a magnetic wire includes: a magnetic layer of soft magnetic material, where the magnetic wire does not require power to persistently store bits in the magnetic layer, and where the magnetic wire is configured to allow the bits to move within the magnetic wire when current is applied to the magnetic wire; and a paramagnetic conductive layer, layered with the magnetic layer, and configured to receive the current, wherein a width of the magnetic layer is less than a width of the paramagnetic conductive layer.

The width of the conductive layer may be at least twice the width of the magnetic layer.

The bits may have an order, and the magnetic wire may be configured to allow the bits to retain their order while the bits move within the magnetic wire.

A reading element may be configured to read the bits, a writing element may be configured to write the bits, and electrodes may be configured to provide current to the magnetic wire.

The magnetic wire may include a linear section that includes the conductive layer and the magnetic layer, the linear section may include opposing edges of the paramagnetic conductive layer that are further apart than opposing edges of the magnetic layer, and magnetic walls between the bits may have less tilt when being moved by the current than if, for the same current, the widths of the paramagnetic conductive layer and the magnetic layer were the same.

Other features and aspects will be apparent from the following detailed description, the drawings, and the claims.

### BRIEF DESCRIPTION OF THE DRAWINGS

FIG. 1 illustrates an example of an operation principle of a magnetic memory, according to one or more embodiments.

FIG. 2 illustrates an example of a tilting of a magnetic domain wall of a magnetic wire, according to one or more embodiments.

FIG. 3 illustrates an example of reducing an effect of an Oersted field generated in a magnetic wire, according to one or more embodiments.

FIG. 4 illustrates an example of a method of manufacturing a magnetic wire, according to one or more embodiments.

FIG. 5 illustrates an example of an edge milling process, according to one or more embodiments.

FIG. 6 illustrates an example of a wire pattern, an electrode pattern and an edge milling pattern, according to one or more embodiments.

FIG. 7 illustrates an example of a graph which shows an atomic force microscopy (AFM) image of a device manufactured by cutting an edge portion of a magnetic wire and a thickness of the cut edge portion, according to one or more embodiments.

FIG. 8 illustrates an example of a method of cutting an edge portion of a magnetic wire, according to one or more embodiments.

FIG. 9 illustrates an example of a method of ablating an edge portion of a magnetic wire to a width of 100 nanometers (nm), according to one or more embodiments.

Throughout the drawings and the detailed description, unless otherwise described or provided, the same drawing reference numerals will be understood to refer to the same elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

The terminology used herein is for describing various examples only and is not to be used to limit the disclosure. The articles “a,” “an,” and “the” are intended to include the plural forms as well, unless the context clearly indicates otherwise. As used herein, the term “and/or” includes any one and any combination of any two or more of the associated listed items. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof.

Throughout the specification, when a component or element is described as being “connected to,” “coupled to,” or “joined to” another component or element, it may be directly “connected to,” “coupled to,” or “joined to” the other component or element, or there may reasonably be one or more other components or elements intervening therebetween. When a component or element is described as being “directly connected to,” “directly coupled to,” or “directly joined to” another component or element, there can be no other elements intervening therebetween. Likewise, expressions, for example, “between” and “immediately between” and “adjacent to” and “immediately adjacent to” may also be construed as described in the foregoing.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment, e.g., as to what an example or embodiment may include or implement, means that at least one example or embodiment exists where such a feature is included or implemented, while all examples are not limited thereto.

Hereinafter, examples will be described in detail with reference to the accompanying drawings. When describing the examples with reference to the accompanying drawings, same or like reference numerals refer to same or like elements and a repeated description related thereto will be omitted.

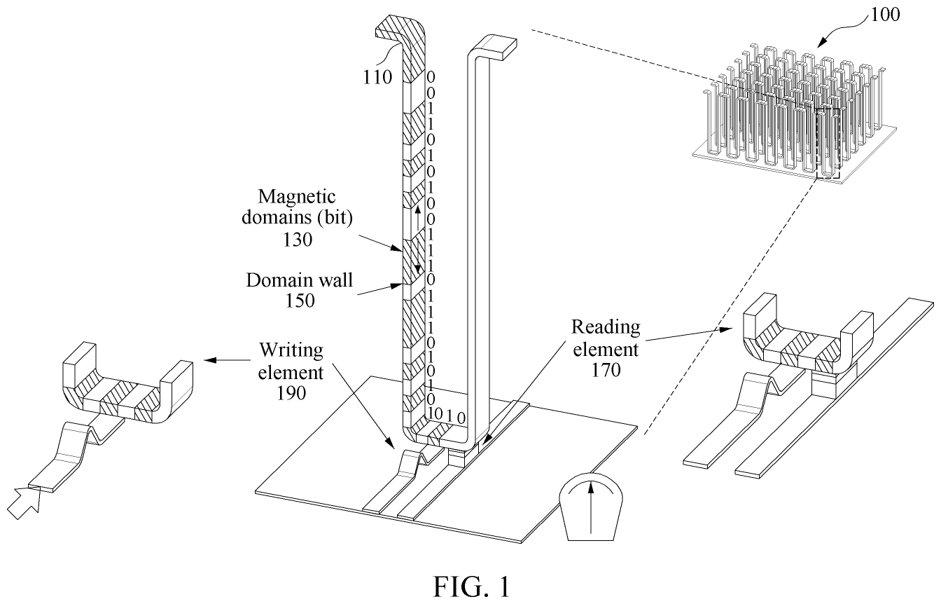

FIG. 1 illustrates an example of an operation principle of a magnetic memory, according to one or more embodiments. FIG. 1 is a conceptual drawing of a magnetic memory 100 based on a magnetic domain wall according to an example.

The magnetic memory 100 may be a storage device based on movement of a magnetic domain wall within a magnetic material. Although a hard disk drive (HDD), for example, is non-volatile in that it maintains information without a power supply (when de-powered), it may consume significant energy and have speed limits because it saves information by rotating a disk. In contrast, the magnetic memory 100 based on the movement of a magnetic domain wall may save/read information by moving a magnetic domain wall in a magnetic nanowire without requiring mechanical rotation or other mechanical action.

The magnetic memory 100 may include, for example, storage tracks 110. Each storage track may store a respective plurality of magnetic domains 130. Each magnetic domain 130 is a very small magnetic area which constitute a magnetic body. Each storage track 110 may be connected to a respective element (not shown) to apply a current to the storage track 110 for effects that are described below.

A storage track 110 may have a laminated structure which includes at least one soft magnetic layer, for example, a cobalt (Co) or Co alloy layer. In this case, the soft magnetic layer may include, for example, one or more of cobalt (Co), nickel (Ni), and/or iron (Fe), but is not limited thereto. In some embodiments, the storage track 110 may have a cobalt-iron (CoFe) soft magnetic layer (or cobalt (Co) layer) and a paramagnetic layer(s) for example platinum (Pt) layer(s) (or palladium (Pd) layer(s)) laminated alternately, but is not limited thereto. The storage track 110 may be composed and constructed to provide a perpendicular magnetic anisotropy which may facilitate magnetic domain wall movement within the storage track 110, for example by applying rapid current pulses through an element of the storage track 110. The geometry of the storage track 110 may vary, for example, it may have a linear shape, a “U” shape, circular/loop shaped, or any shape suitable for variables, materials, etc., of various embodiments.

A storage track 110 may be provided with a reading element 170 for reproducing data (reading stored data) from the storage track 110 and a writing element 190 for writing data to the storage track 110. The writing element 190 and reading element may be disposed to operate on respective physical portions of the storage track 110. The reading element 170 and the writing element 190 may each be configured and arranged relative to the storage track 110 according to features of a magnetic domain 130. The reading element 170 and the writing element 190 may use a tunnel magneto resistance (TMR) effect or a giant magneto resistance (GMR) effect; devices using the TMR and GMR effects are well known and detailed description thereof is available elsewhere.

The principle and structure of the reading element 170 and the writing element 190 are not limited thereto and may be variously modified. For example, the writing element 190 may be a device for writing data using an external magnetic field. In this case, the storage track 110 and the writing element 190 may be spaced apart from each other by a predetermined distance. Also, instead of providing the reading element 170 and the writing element 190 separately, a single reading/writing element may be provided which provides both reading and writing functions.

A first conductive wire (not shown) and a second conductive wire (not shown) may be provided, which are in contact with respective ends of the storage track 110. The first conductive wire and the second conductive wire may be connected with a first driving element (not shown) and a second driving element (not shown), respectively. The first driving element and the second driving element may be, for example, transistors, diodes, or the like.

Predetermined amounts of pulses of current are applied to the storage track 110 through the first driving element and/or the second driving element to move a magnetic domain wall 150 by bit-equivalent increments, thus allowing the magnetic memory 100 to reproduce (read) and/or record data of a specific bit whose magnetic domain walls 150 is moved for alignment with a reading/writing element (as the case may be) by the current pulses. Here, the magnetic memory 100 may apply reading current to the reading element 170 to reproduce (read) data recorded in the storage track 110 at the magnetic domain 130 currently aligned therewith, and/or apply writing current to the writing element 190 to record (store) data in the magnetic domain 130 of the storage track 110 that is currently aligned with the writing element 190.

The magnetic memory 100 may facilitate transfer of data by using a pulse current to induce a motion of the magnetic domain wall 150, which is caused by a combination of (i) magnetic domains 130, each of which can be used as a respective digitalized data bit, and (ii) a spin current, which is a driving force for moving the plurality of magnetic domains 130. The magnetic domains 130, for example, may include an up domain, which may be used as data bit “0”, and a down domain, which may be used as data bit “1”. Here, a magnetic domain wall 150 is a boundary between two magnetic domains 130 that have different directions of magnetization, that is, a magnetic domain wall 150 is a boundary between the N pole and the S pole. The magnetic domain wall 150 may have a predetermined volume/area and may be moved within the magnetic body due to the current applied to the magnetic body. More specifically, the magnetic domain wall 150 may be moved by applying a torque to the magnetic domain wall 150 with an electron which has a predetermined spin direction, by applying current to the magnetic body which has the magnetic domain wall 150. This movement may be referred to as the movement of the magnetic domain wall 150 by a spin transfer torque.

The operating speed of the magnetic memory 100 may be enhanced by increasing the movement speed of the magnetic domain wall 150, since the movement speed of the magnetic domain wall 150 is directly related to the operating speed (e.g., the “seek” speed) of the memory in the magnetic memory 100.

However, when measuring the movement speed induced by a driving element of the magnetic memory 100, an Oersted field, which is produced by the magnetic wire itself and which has an appreciable width of tens of micrometers, may inevitably affect the shape of the magnetic domain wall 150 when in motion. The Oersted field, according to the laws of physics, is a magnetic field created by an electric current. More specifically, due to the Oersted field, a magnetic field may surround a wire in which current flows and may be in a plane perpendicular to the wire, and the direction of the magnetic field may change if the direction of the current changes. In this case, the strength of the magnetic field is proportional to the strength of the current, and the strength of the magnetic field at any point is inversely proportional to the distance from the wire to the point.

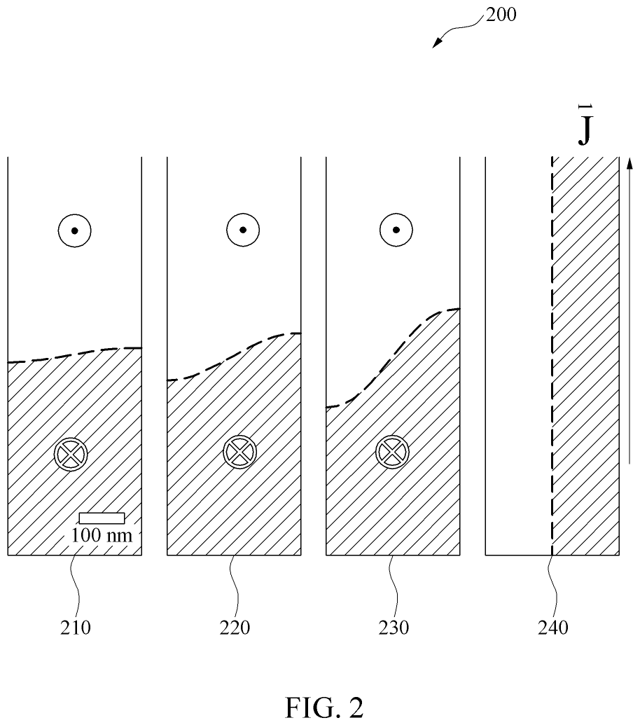

When current is induced to move the magnetic domains, the Oersted field may cause the magnetic domain walls 150 to tilt and make it difficult to accurately measure the speed of the magnetic domain walls. The tilting of a magnetic domain wall is described in more detail with reference to FIG. 2.

FIG. 2 illustrates an example of a tilting of a magnetic domain wall of a magnetic wire. Referring to FIG. 2, a current [symbol] , which is applied to the magnetic wire causes an Oersted field which tilts the magnetic domain wall. A simulation result of the tilting is illustrated in the drawings 210, 220, 230, and 240.

If the current [symbol] is consistently applied to the magnetic wire, the current [symbol] may tilt the magnetic domain wall more and more from an almost horizontal form as shown in drawing 210 to the form shown in drawings 220 and 230, and to the vertical form as shown in drawing 240. The symbol [symbol] in FIG. 2 represents the direction (e.g., up domain) in which a magnetization, which corresponds to a magnetic domain, comes out vertically from, or normal to a plane of the screen/drawing, and the symbol [symbol] represents the direction (e.g., down domain) in which a magnetization, which corresponds to a magnetic domain, goes in vertically to the plane of the screen/drawing.

Tilting of the magnetic domain wall may be caused by the boundary between the up domain, which may be used as the data bit “0”, and the down domain, which may be used as the data bit “1”, becoming unclear due to the Oersted field, which is caused by the current [symbol] that is applied to the magnetic wire to move the data bits through the storage track (refer to the storage track 110 of FIG. 1) of the magnetic memory.

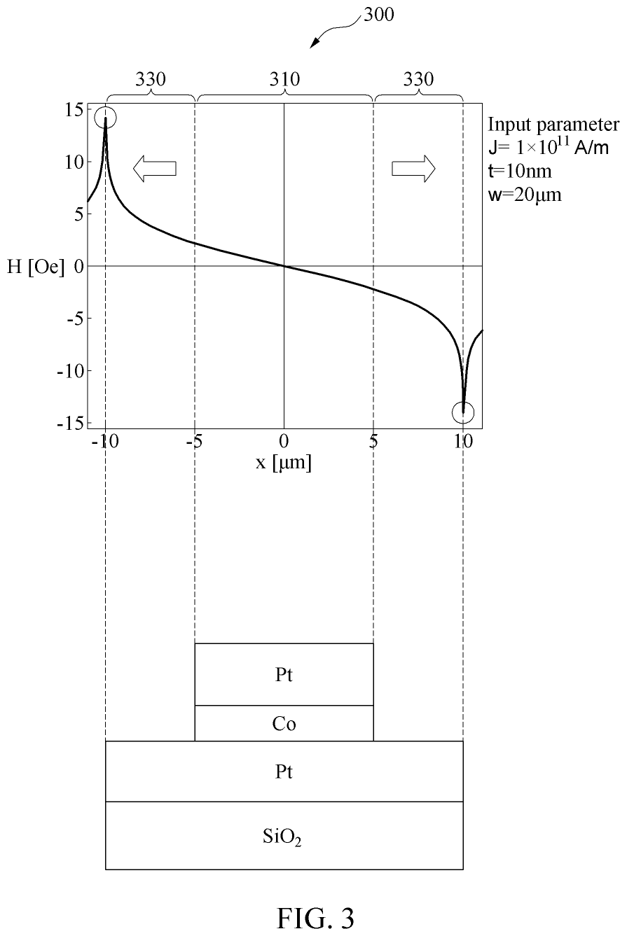

FIG. 3 illustrates an example of reducing an effect of Oersted field generated in a magnetic wire. Referring to the graph 300 of FIG. 3, which is juxtaposed with a magnetic wire cross-section, when current is applied which drives the magnetic domain wall of the magnetic wire, an Oersted field occurs, and the magnetic field greatly increases at the edge portions 330 of the magnetic wire. Note that “edge portion” refers to cross sectional areas of the magnetic wire (or portions removed therefrom, depending on context). The graph 300 illustrates strength of the Oersted field (in Oe units) as a function of position from the center of the magnetic wire whose cross section is illustrated below the graph 300.

When the current which drives the magnetic domain wall is applied to the magnetic wire (e.g., to a Pt layer in FIG. 3), the Oersted field affects both edge portions 330 of the magnetic wire (“magnetic wire” here collectively referring to the wire layers above the substrate), which may deform the magnetic domain wall.

In the example shown in FIG. 3, opposing edges of the upper layers of the magnetic wire corresponding to the edge portions 330 (where the magnetic field is greatest), may be brought inward (toward each other) by cutting through (ablating) by ion milling, thereby reducing the width of the magnetic domain walls relative to the overall width of the magnetic wire, which reduces the impact of the Oersted field on the magnetic domain walls passing through the remaining (un-milled) central part 310 of the upper layers, since the Oersted field is strongest at the edges of the magnetic wire. Although ion milling is convenient, any means of construction or providing different layer widths may be used. In some embodiments, a current-carrying lower conductive paramagnetic layer (e.g., lower Pt layer in FIG. 3) may be wider than an upper soft magnetic layer (e.g., the Co layer shown in FIG. 3). That is, an edge portion 330 of the lower Pt layer, for example, may be retained or otherwise configured to be wider than the upper layers. Any means of providing such structure may be used.

The magnetic wire according to an example may be configured/constructed such that the edge portion 330 are cut by a predetermined width ratio of the total width of the magnetic wire (i.e., a ratio of the width of the removed/omitted portion to an overall wire width), and the ratio may be such that the magnetic domain wall of the magnetic wire (specifically, in the narrower soft magnetic layer) has reduced (or tolerable) tilt due to the Oersted field generated by the current applied to the magnetic wire. The predetermined width ratio may be, for example, a width ratio of ¼ of the total width of the magnetic wire but may vary according to implementation details, desired performance, etc. In the example of FIG. 3, the ratio is 5 μm/20 μm.

Here, the edge portion 330 of the magnetic wire may be cut to a small/negligible thickness (for practical purposes, “removed”) such that current flows in the edge portion 330 of the underlying paramagnetic layer but the magnetic layer of the edge portion is not magnetized (i.e., the relatively very thin remaining soft magnetic material has no practical effect). The magnetic layer of the edge portion 330 may be cut to a small/negligible thickness of, for example, 0.0075% of the total width of the magnetic wire, but is not limited thereto. The edge portion 330 of the magnetic wire may be etched down through the edge portion of the magnetic layer using, for example, an argon (Ar) ion-beam etching, but is not limited thereto. As referred to herein, such negligible magnetic material (after ablating/cutting) at the edge portion is excluded from consideration when referring herein to the width of the final magnetic layer. In other words, although a slight amount of magnetic material may remain on the underlying paramagnetic layer at the edges, such marginal magnetic material is not functional, is not considered to be part of the magnetic layer, and is not considered to be part of the width of the ablated magnetic layer.

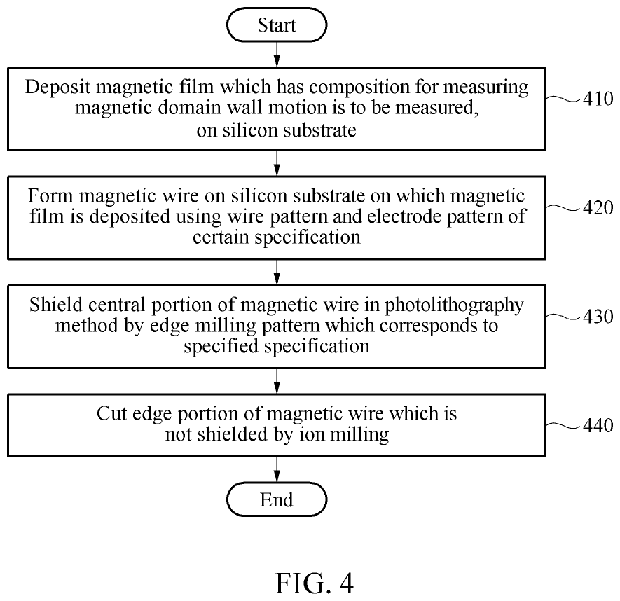

The edge portion 330 of the magnetic wire may be cut or removed to a thickness at which current flows in the edge portion 330 of the underlying paramagnetic layer but the magnetic layer of the edge portion 330 is not magnetized based on a polar-magneto-optical Kerr effect (P-MOKE), and a central portion 310 of the magnetic wire may be shielded in a photolithography method by an edge milling pattern corresponding to a predetermined specification. The P-MOKE is described with reference to FIG. 4.

FIG. 4 illustrates an example of a method of manufacturing a magnetic wire, according to one or more embodiments. In the following examples, operations may be performed sequentially, but are not necessarily performed sequentially. For example, the order of the operations may be changed and at least two of the operations may be performed in parallel.

Referring to FIG. 4, a manufacturing apparatus according to an example may generate an edge-milled magnetic wire through operations 410 to 440.

In operation 410, the manufacturing apparatus deposits a magnetic film, which may have a composition suitable for measuring the motion of the magnetic domain wall, on the silicon substrate (“on the silicon substrate” does not require the magnetic film to be deposited directly on the silicon substrate; there may be intervening layer(s), e.g., a paramagnetic layer, i.e., the magnetic film is deposited above the silicon substrate and may or may not be in direct contact with the silicon substrate). The manufacturing apparatus may deposit the magnetic film, which has a composition that is amenable to be measured (discussed below), on a silicon substrate using, for example, a DC magnetron sputtering technique. Here, the “magnetron sputtering” technique may correspond to a deposition method which forms a uniform magnetic field by focusing a DC plasma around a negative target with a magnetic field generated by a strong permanent magnet. By configuring a high plasma density by the magnetron sputtering technique, the pressure required for plasma formation may be reduced to 1/10, and the deposition speed may be enhanced by about 10 to 100 times. More specifically, in the magnetron sputtering technique, free electrons move helically and are accelerated due to the Lorentz force by a permanent magnet and a cathode/anode electric field, and the free electrons collide more with neutral argon (Ar) in the plasma, increasing the plasma density, and the sputtering efficiency may be increased by focusing the plasma around the cathode.

The magnetic film may include, for example, a magnetic film of perpendicular magnetic anisotropy having a vertical magnetization state, but is not limited thereto.

In operation 420, the manufacturing apparatus forms a magnetic wire on the silicon substrate on which the magnetic film is deposited using a wire pattern and an electrode pattern of a predetermined standard. The manufacturing apparatus may deposit by photolithography (PR), for example, material of a wire pattern and an electrode pattern, and a wire width of the wire pattern may be wider than the width W of the magnetic wire on the silicon substrate on which the magnetic film is deposited.

Photolithography, may correspond to, for example, a process of engraving a pattern on a circuit, similar to taking a picture, by applying a photoresist, which is a photosensitizer, to a wafer and irradiating (exposing) the wafer with light. In the photolithography process, light with a wavelength generally below the ultraviolet range (e.g., an excimer laser) may be used to precisely engrave the patterns on the circuits.

The photolithography process may be performed, for example, in the following order: apply a liquid or gas adhesion promoter such as hexamethyldisilazane (HMDS) to the wafer, apply photoresist (PR), soft bake, exposure, post-exposure bake (PEB), develop, hard bake, etching, and photoresist (PR) removal may be performed but is not necessarily limited thereto.

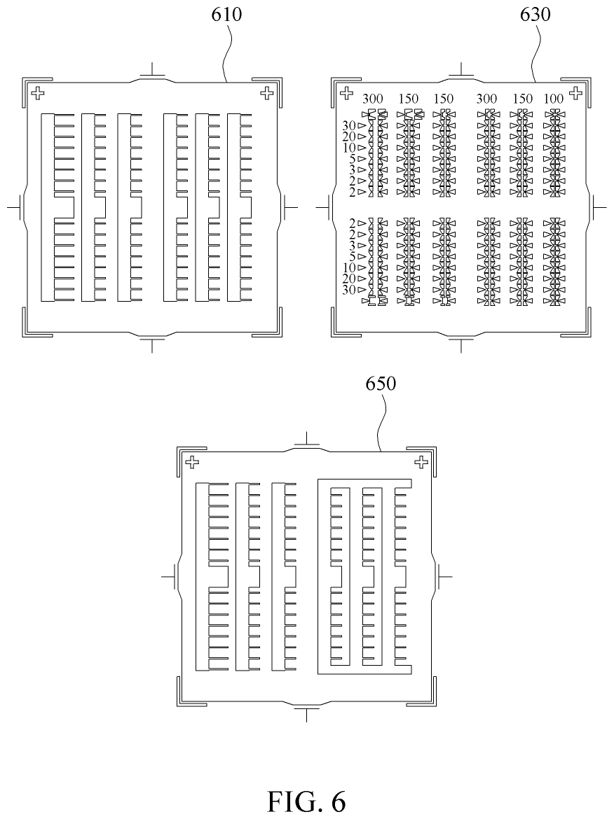

An example of a wire pattern and an electrode pattern used to form a magnetic wire in an example may refer to a wire pattern 610 and an electrode pattern 630 of FIG. 6 described below.

In operation 430, the manufacturing apparatus may shield the central portion of the magnetic wire in a photolithography method by an edge milling pattern corresponding to a predetermined specification. An example of the edge milling pattern may refer to the edge milling pattern 650 of FIG. 6 described below.

In operation 440, the manufacturing apparatus may cut an edge portion of an unshielded magnetic wire by ion-milling. Here, “ion milling” may refer to, for example, a method of cutting (milling) a part to be cut by accelerating the ions of an inert gas such as Argon with a surface or cross section of a vacuum substrate(specimen) and then irradiating them on the sample (e.g., magnetic wire). Here, if the ions or atoms of the inert gas are accelerated by an appropriate voltage and continuously collide with the center of the substrate of a diameter of several millimeters (mm), a sputtering phenomenon occurs, in which atoms on the surface of the substrate are separated, and the central portion of the substrate may be polished mainly and intensively. The energy value applied to the ion can be mainly used, for example, in the range of 3-6 keV in the case of Argon. The ion beam may have a large impact on the angle of incidence that strikes the substrate surface, the polishing rate, the polish state of the surface, the depth of microstructure damage, and so on. In general, an ion beam is mainly used in the range of 10-20° and can induce uniform polishing by rotating the substrate.

In operation 440, the manufacturing apparatus may etch the edge portion of the magnetic wire up to the magnetic layer through, for example, Ar ion-beam etching. The manufacturing apparatus may cut the edge portion to a thickness at which the current flows in the edge portion of the magnetic wire, but the magnetic layer of the edge portion is not magnetized.

The manufacturing apparatus may measure, for example, the P-MOKE for the (edge portion of the) magnetic body wire and may use the measurement result to cut the edge portion to the thickness at which the current flows in the edge portion of the magnetic wire but the magnetic layer of the edge portion is non-magnetic.

For example, when a polarized laser is reflected after being incident on the surface of the magnetic layer of the magnetized magnetic thin film, the polarization direction may change due to the difference between the incident light and the reflected light. The change occurring between the incident light and the reflected light as described above may be referred to as the “magneto-optic Kerr effect (MOKE)”. The P-MOKE may be applicable when the magnetization direction of an object is parallel to the plane of incidence (or reflection plane) of the light and is vertical to the surface of the object.

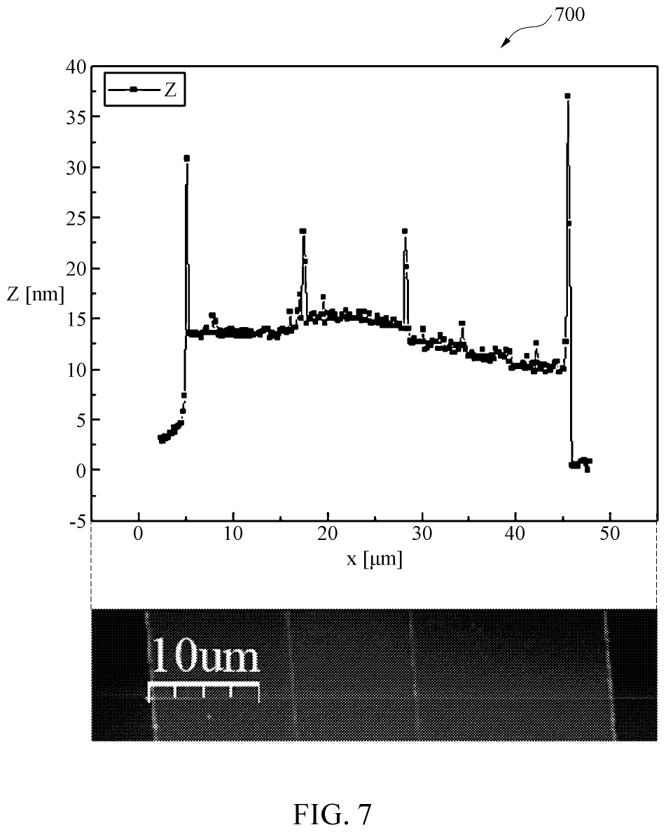

The manufacturing apparatus may cut the magnetic layer of the edge portion, to a thickness ratio of, for example, 0.0075% of the total width of the magnetic wire. The thickness ratio by which the edge portion of the magnetic wire is cut by the manufacturing apparatus is described in more detail with reference to FIG. 7 below.

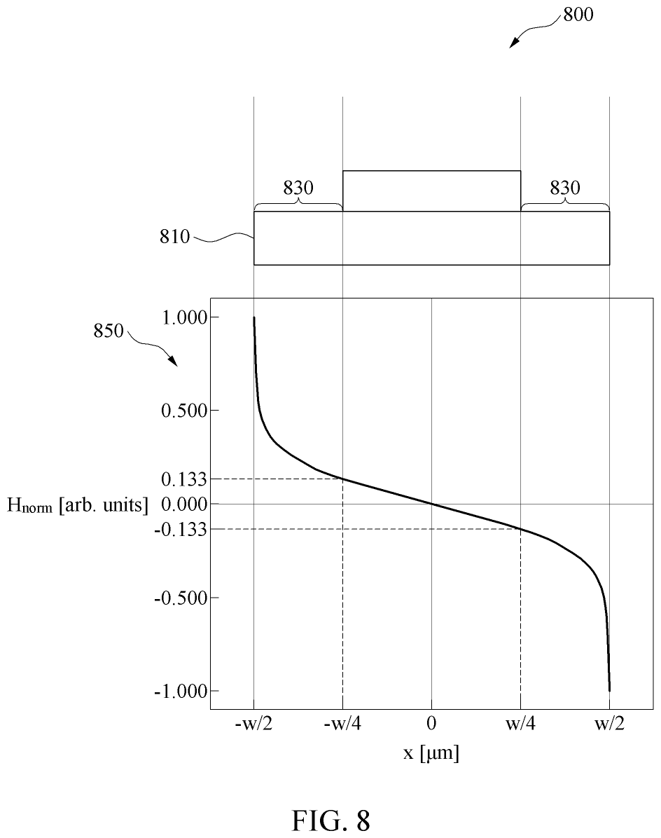

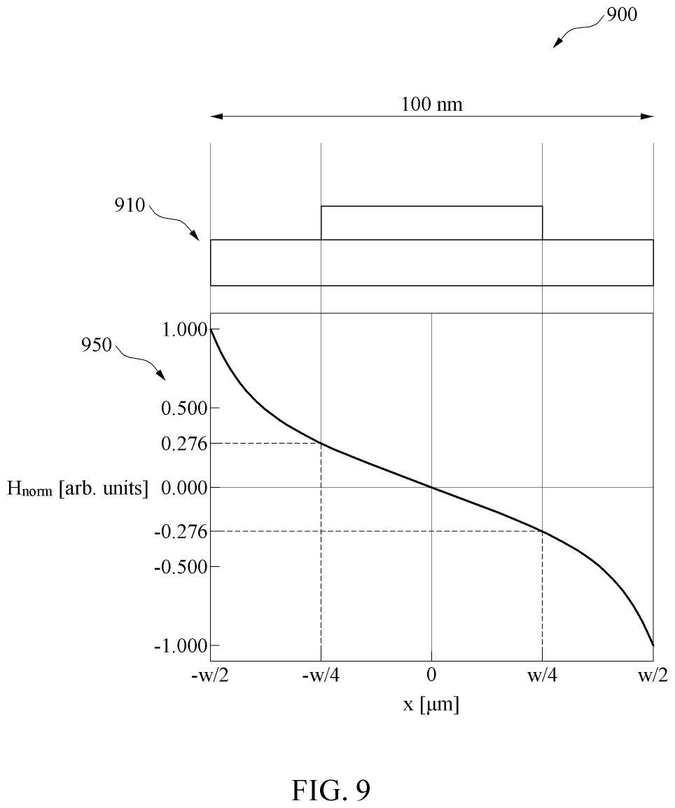

Or, the manufacturing apparatus may, for example, cut the edge portion of both ends of the magnetic wire by a width ratio of ¼ of the total width W of the magnetic wire. The width by which the manufacturing apparatus cuts the edge portion of the magnetic wire is described in more detail with reference to FIGS. 8 to 9 below.

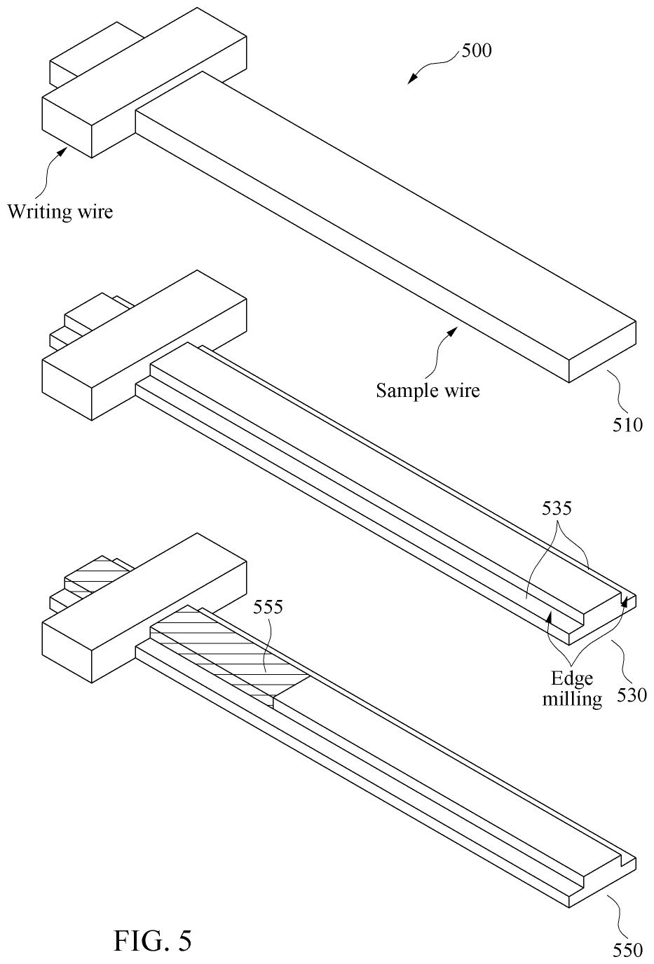

FIG. 5 illustrates an edge milling process according to an example, and FIG. 6 illustrates an example of a wire pattern, an electrode pattern, and an edge milling pattern according to an example.

Referring to FIG. 5, a process in which a manufacturing apparatus performs edge milling on a magnetic wire is illustrated as indicated by reference number 500. Referring to FIG. 6, a wire pattern 610, an electrode pattern 630, and an edge milling pattern 650 examples are shown.

As indicated by reference number 510, the manufacturing apparatus may deposit a thin magnetic film using DC magnetron sputtering, and the magnetic film may have a composition suitable for measuring the motion of the magnetic domain wall, on the silicon substrate as a sample wire.

The manufacturing apparatus may form the magnetic wire by milling an edge portion 535 by photolithography and Argon (Ar) ion milling, as indicated by reference number 530, using a wire pattern (e.g., the wire pattern 610 of FIG. 6) which is designed to be about 30 micrometers, which is wider than the magnetic wire. Here, the manufacturing apparatus may find a condition in which the MOKE signal does not appear at the edge portion of the magnetic wire while ion milling is performed.

The manufacturing apparatus may perform photolithography, electrode deposition, and a lift-off process by using an electrode pattern (e.g., the electrode pattern 630 of FIG. 6) suitable for the wire pattern 610.

The manufacturing apparatus may shield a central portion 555 of the magnetic wire through photolithography using an edge milling pattern (e.g., the edge milling pattern 650 of FIG. 6) as indicated by reference number 550.

The manufacturing apparatus may cut (ablate) the magnetic layer area of the edge portion 535 of the unshielded magnetic wire through ion milling to erase the magnetism of the edge area of the magnetic wire while still allowing the current to flow via the un-milled/lower Pt layer.

The edge-milled magnetic wire produced through the above process may dramatically reduce the tilting of the magnetic domain wall during current-induced domain-wall motion, unlike in general micro-wires. In addition, the disappearance of some domains of the magnetic wire may be prevented through edge milling when a high-density current is applied to the magnetic wire.

The edge-milled magnetic wire reduces the tilted angle of the magnetic domain wall, thereby reducing the spin orbit torque generated by the tilting angle of the magnetic domain wall, realizing more efficient and fast magnetic domain wall motion. Also, the edge-milled magnetic wire may utilize most or all of the area of the magnetic wire by reducing the influence of the Oersted field on the soft magnetic layer.

FIG. 7 illustrates an example of a graph which shows an atomic force microscopy (AFM) image of a device manufactured by cutting an edge portion of a magnetic wire and a thickness of the cut edge portion. Referring to FIG. 7, a graph 700 is shown corresponding to an AFM image of a device (e.g., magnetic memory) manufactured by edge milling a magnetic wire of 40 um width W to a 20 um width center portion according to an example.

AFM is a high-resolution non-optical imaging technology which can accurately and non-destructively measure the topography, electrical, magnetic, chemical, optical, and mechanical characteristics of the sample surface with very high resolution in air, liquid, or ultra-high vacuum, and thereby generate a three-dimensional topographical image of the sample surface. The AFM image may correspond to a three-dimensional image which measures the surface of the magnetic wire as it appears after cutting the edge portion of the magnetic wire.

The edge portion of the magnetic wire may be cut to a negligible thickness such that when current flows any remaining negligible magnetic layer of the edge portion is not magnetized. Here, the thickness at which current flows but the negligible magnetic layer of the edge portion is not magnetized may be, for example, 3 nm, which is 0.0075% the width of 40 um, which is the total width of the magnetic wire, but the present disclosure is not necessarily limited thereto.

In one example, it may be determined by the AFM image whether, for example, there is damage on the surface of the magnetic wire due to ion milling, whether the photoresist (PR) remains after erasing patterns such as the wire pattern and electrode pattern, and/or whether the desired width has been cut from the magnetic wire.

In the graph 700 of FIG. 7, X may represent an arbitrary horizontal axis X appearing in an AFM image of a size of 50×50 micrometers (μm), and Z may represent a vertical axis which corresponds to the height.

FIG. 8 illustrates an example of a method of cutting an edge portion of a magnetic wire, according to one or more embodiments. FIG. 8 shows a drawing 800 which shows a cross section 810 illustrating an edge portion 830 of the magnetic wire, and a graph 850 illustrating the magnetic field which appears in the magnetic wire as current is applied to the magnetic wire, according to an example.

In one example, as shown in the graph 850, the edge portion 830 of both edges/sides of the upper layers of the wire may be ion-milled to a ratio of ¼ of the total width W of the magnetic wire (i.e., the width of a milled edge region may be ¼ of the total width). When the width of the upper soft-magnetic layer of the magnetic wire is reduced to half of the total width of the magnetic wire through ion milling as described above, the magnetic field generated at the edge by the electric current may be reduced to less than 30% from 19.91 Oe to 2.20 Oe (here, “width” of the upper soft-magnetic layer excludes any negligible magnetic layer remaining on the underlying paramagnetic layer).

FIG. 9 illustrates an example of a method of cutting an edge portion of a magnetic wire with a width of 100 nm, according to one or more embodiments. FIG. 9, according to an example, shows a drawing 900 illustrating a graph 950, which illustrates a magnetic field strength which occurs in the magnetic wire as the current is applied to the magnetic wire and the cross section 910 of the magnetic wire, in a case where the width W of the magnetic wire is 100 nm and the edge portion of both sides of the magnetic wire is ion milled by W/4.

When the edge portions of both ends of the magnetic wire are milled by W/4=100 nm/4=25 nm, respectively, the width of the central (non-milled) portion of the magnetic wire may be 50 nm. Here, the magnetic field generated at both edge portions may be reduced by about 27%, from ±1.000 Oe to ±0.276 Oe, as shown in the graph 950. When the magnetic field is reduced as previously described, it is possible to realize faster magnetic domain wall motion by dramatically reducing the tilting of the magnetic domain wall caused by the current at the edge portion. As used herein “no tilt” or the like does not necessarily require literally zero tilt, but rather allows for some minor amount tilt that does not impair operation as a memory device or does not lower performance of a memory device.

The computing apparatuses and methods described herein with respect to FIGS. 1-9 are implemented by or representative of hardware components. Examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. A hardware component may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in FIGS. 1-9 that perform the operations described in this application are controlled/performed by computing hardware, for example, by one or more processors or computers, implemented as described above implementing instructions or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media. Examples of a non-transitory computer-readable storage medium include read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-Res, blue-ray or optical disk storage, hard disk drive (HDD), solid state drive (SSD), flash memory, a card type memory such as multimedia card micro or a card (for example, secure digital (SD) or extreme digital (XD)), magnetic tapes, floppy disks, magneto-optical data storage devices, optical data storage devices, hard disks, solid-state disks, and any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above disclosure, the scope of the disclosure may also be defined by the claims and their equivalents, and all variations within the scope of the claims and their equivalents are to be construed as being included in the disclosure.

What is claimed is:

1. A method of manufacturing a magnetic wire, the method comprising:
depositing a magnetic film, which has a composition that enables measuring movement of a magnetic domain wall in the magnetic film, above a silicon substrate;
forming a magnetic wire on the silicon substrate, above which the magnetic film is deposited, using a wire pattern and an electrode pattern of a predetermined specification;
shielding a central part of the magnetic wire in a photolithography method by an edge milling pattern corresponding to the predetermined specification; and
ablating an edge portion of the unshielded magnetic wire by ion-milling.

2. The method of claim 1, wherein the ablating of the edge portion reduces the edge portion of the magnetic wire to a thickness at which a current flows in the edge portion but a magnetic layer is not magnetized.

3. The method of claim 1, wherein the ablating of the edge portion of the magnetic wire comprises:
measuring a polar-magneto-optical Kerr effect (P-MOKE) of the edge portion of the magnetic wire; and
ablating the edge portion of the magnetic wire to a thickness at which a current flows in the edge portion but a magnetic layer is not magnetized, using a result of the measuring of the P-MOKE.

4. The method of claim 1, wherein the ablating of the edge portion of the magnetic wire comprises cutting a magnetic layer of the edge portion to a thickness ratio of 0.0075% of a total width of the magnetic wire.

5. The method of claim 1, wherein the ablating of the edge portion of the magnetic wire reduces a width of an ablated layer of the magnetic wire to one half of the total width of the magnetic wire.

6. The method of claim 1, wherein the ablating of the edge portion of the magnetic wire comprises etching the edge portion of the magnetic wire down through a magnetic layer, using argon (Ar) ion-beam etching.

7. The method of claim 1, wherein the magnetic film comprises a magnetic film of perpendicular magnetic anisotropy having a vertical magnetic state.

8. The method of claim 1, wherein the depositing of the magnetic film on the silicon substrate comprises depositing the magnetic film on the silicon substrate using direct current (DC) magnetron sputtering.

9. The method of claim 1, wherein the wire pattern which has a pattern wire width that is wider than a width W of the magnetic wire, and wherein the magnetic film is deposited using a photolithography.

10. A magnetic wire comprising:
opposing edge portions, wherein each edge portion is cut in a predetermined width ratio relative to a total width of the magnetic wire so that a magnetic domain wall of the magnetic wire does not tilt due to an Oersted field which occurs due to a current applied to the magnetic wire.

11. The magnetic wire of claim 10, wherein the predetermined width ratio comprises a width ratio of ¼ of the total width of the magnetic wire.

12. The magnetic wire of claim 10, wherein the edge portion is cut to a thickness at which the current flows in the edge portion but a magnetic layer of the edge portion is not magnetized.

13. The magnetic wire of claim 10, wherein a thickness of a magnetic layer of the edge portion is cut to 0.0075% of the total width of the magnetic wire.

14. The magnetic wire of claim 10, wherein the magnetic wire is etched down through a magnetic layer of the edge portion through Argon (Ar) ion-beam etching.

15. The magnetic wire of claim 10, wherein
the edge portion is cut to a thickness at which the current flows in the edge portion but a magnetic layer of the edge portion is not magnetized based on a result of the measuring of the P-MOKE of the edge portion, and
a central part of the magnetic wire is shielded in a photolithography method by an edge milling pattern corresponding to a predetermined specification.

16. A magnetic wire comprising:
a magnetic layer of soft magnetic material, wherein the magnetic wire does not require power to persistently store bits in the magnetic layer, and wherein the magnetic wire is configured to allow the bits to move within the magnetic wire when current is applied to the magnetic wire; and
a paramagnetic conductive layer, layered with the magnetic layer, and configured to receive the current, wherein a width of the magnetic layer is less than a width of the paramagnetic conductive layer.

17. The magnetic wire of claim 16, wherein the width of the conductive layer is at least twice the width of the magnetic layer.

18. The magnetic wire of claim 16, wherein the bits have an order, and wherein the magnetic wire is configured to allow the bits to retain their order while the bits move within the magnetic wire.

19. The magnetic wire of claim 18, further comprising a reading element configured to read the bits, a writing element configured to write the bits, and electrodes configured to provide current to the magnetic wire.

20. The magnetic wire of claim 19, wherein the magnetic wire comprises a linear section comprising the conductive layer and the magnetic layer, the linear section comprising an opposing edges of the paramagnetic conductive layer that are further apart than opposing edges of the magnetic layer, and wherein magnetic walls between the bits have less tilt when being moved by the current than if, for the same current, the widths of the paramagnetic conductive layer and the magnetic layer were the same
